(19) United States
(12) Patent Application Publication
(10) Pub. No.: US 2003/0204856 A1
(43) Pub. Date: Oct. 30, 2003

(54) Distributed server video-on-demand system

(76) Inventor: Mark J. Buxton, Chandler, AZ (US)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/135,539

(22) Filed: Apr. 30, 2002

(51) Int. Cl. H04L 1/22; H04B 1/74; H02H 3/05; H05K 10/00; H03K 19/003; H04N 7/173; H04N 7/16

(52) U.S. Cl. 725/120; 725/98; 725/115; 725/145; 714/6

(57) ABSTRACT

A apparatus and method for effecting a distributed video on demand system is a local data network. A number of local processing units within the local network are utilized, with the local processing units being associated with system subscribers of the video on demand system. The local processing units include memories that are each configured to store video data. A database server in communication with local data network is further included for directing streamed delivery of the video data from certain ones of the local processing units storing particular video data to other local processing units in the local network that are requesting playback of the particular video data.

### FIELD OF THE INVENTION

The present invention relates to video-on-demand (VOD) systems and, more particularly, to a video on demand system using distributed storage of multimedia or video data.

### BACKGROUND

Video-on-demand (VOD) is becoming increasingly attractive to consumers requesting high quality video playback in real-time or near real-time. Higher rates of data transfer in the latest network technology makes possible VOD systems where user-subscribers may request stored video data, such as television shows or movies, via a data network. Typically a VOD system must have the capability of delivering videos from a very large collection (e. g., tens of thousands of videos) to a relatively smaller number of user-subscribers (e. g., thousands). In previous VOD systems, videos were stored on tertiary storage devices, which become very costly when required to store hundreds of terabytes of data on media such as arrays of magnetic tape (e.g., VHS), magnetic disks and optical disks. Limited network bandwidth and the desire for low-latency access, however, has driven the shift in VOD systems from large storage devices to the use of turnkey storage additions to existing servers and distributed storage.

Particularly in the case of distributed storage systems, known architectures, such as the Berkeley-distributed VOD system, utilize a database, one or more video file servers, and one or more archive servers. The database contains information about the videos stored in the distributed system. The video file servers store videos on magnetic disks for real-time playback and the archive servers manage the database and one or more tertiary storage devices (e.g., tape jukeboxes). Although architectures such as the Berkeley VOD have been shown to reduce access latency, these systems, nonetheless, still require the use of multiple video file servers to store data, which keeps system costs high. Furthermore, because larger numbers of file servers becomes prohibitive cost wise, partitioning of video data across the system is limited, thereby limiting further reduction of access latency.

Further, peer-to-peer systems are rapidly proliferating and maturing. An example of a peer-to-peer system is FreeNet, which uses a large network of distributed servers. However, the distributed servers do not receive information concerning the content of the data that they are storing (i.e., they are unmanaged), are not optimized for local access patterns and are unconcerned with latency of the data when determining content availability. Additionally, these systems do not work well with managed, transactional networks such as pay-per-view and cable television networks.

### BRIEF DESCRIPTION OF THE DRAWINGS

FIG. 1 illustrates an example video-on-demand system constructed in accordance with the teachings of the present invention.

FIG. 2 illustrates an example table that is utilized in the distributed database server illustrated in FIG. 1.

FIG. 3 illustrates an internal block diagram of the distributed database server illustrated in FIG. 1.

FIG. 4 is a flow diagram illustrating operation of the system of FIG. 1.

FIG. 5 illustrates an alternative video-on-demand system configuration.

### DETAILED DESCRIPTION OF THE PREFERRED EXAMPLES

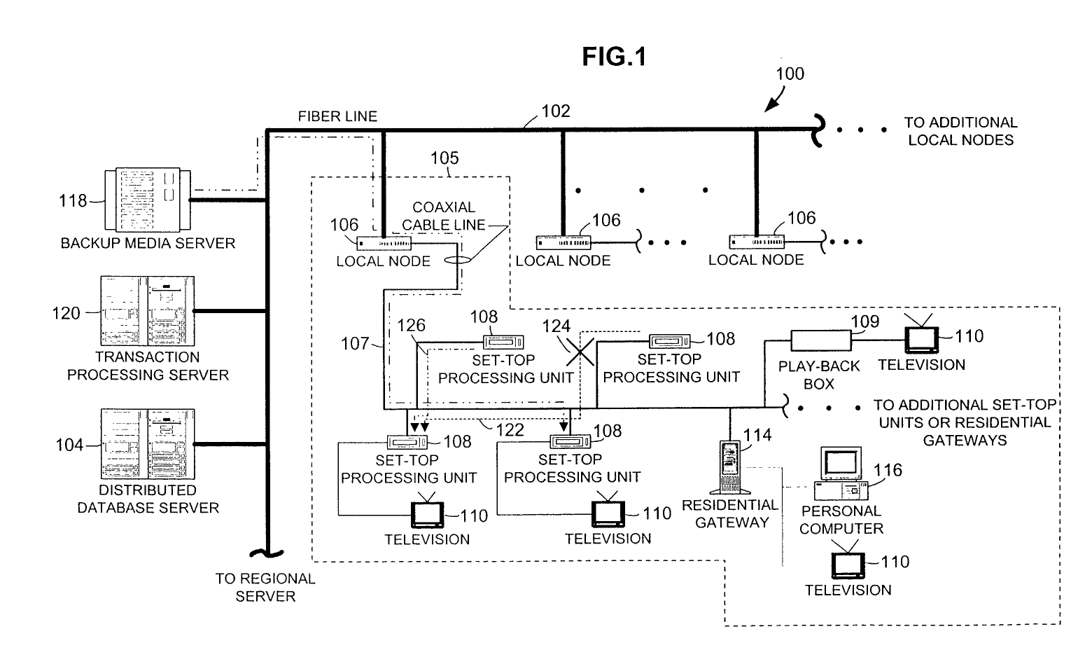

FIG. 1 illustrates a large-scale architecture of a video-on-demand system 100. Various components of the system 100 are connected via a network 102. In the illustrated example, the network includes a fiber line. The illustrated network 102 is a packet-based network utilizing IP protocol or other known packet-based protocols. The video-on-demand system 100 utilizes a peer-to-peer architecture where unused hard-disk capacity of devices associated with corresponding user-subscribers is utilized to store multimedia data or information, such as movies. Management of the peer-to-peer storage is accomplished by at least one distributed database server 104 connected to the network 102. The distributed database server 104 manages a plurality of local networks 105 that each include at least one local node server 106 and may be comprised of local cable television networks, for example. The distributed database server 104 may serve approximately 20,000-50,000 user-subscribers and manage the transmission of data between those users. Each of the local node servers 106 is typically configured to serve approximately 500 to 1000 user subscribers.

As further shown, the network 102 may be connected at a head end to a regional server which is connected to a wider area network, for example. Connection to a wider area network may serve to allow the system 100 to receive streamed movie or video data from longer regional servers (not shown).

Within the local network 105, the local node 106 is connected to a number of user-subscribers in an architecture similar to existing local cable networks. As shown, a network line 107, such as a coaxial cable line, is connected to the local node 106 and supplies data and signaling information to the user-subscribers. A set-top processing unit 108, similar to set-top boxes presently used in local cable network is associated with each of the particular user-subscribers. The set-top processing units 108, however, may be different from standard set-top boxes in that they are configured with the capability to decrypt and play video content streamed over line 107 in the local network 105. Furthermore, the set-top processing units 108 are configurable with the capability to locally stream encrypted video or multimedia data over the line 107 to other set top processing units 108.

In order to store video data, the set-top processing units 108 are equipped with large-capacity hard-disk drives, which typically will have unused storage capacity during normal usage. It is this unused hard-disk storage capacity that is utilized in the present system to store movie and video data. Other memory devices besides hard-disk drives may be utilized within the set-top processing units 108, but magnetic disk drives are preferable in that they have the capability of being searched for content in a relatively short period of time. The set-top processing units 108 may also be comprised of such devices as digital personal recorders (DPR) or digital video recorders (DVR), such as those used in TiVo® systems. It is further noted that utilization of the present system with existing cable network infrastructures may require modification of the physical networks to accommodate increased packet-based communication bandwidth that is presented by locally streaming data over the network line 107.

Additionally, set-top playback units 109 may further be connected in the local network 105 and associated with user-subscribers. The units 109 contain only a decoder to decrypt encrypted video data sent over the network line 107 and are unable to stream video content onto the network line 107.

As further shown in FIG. 1, typically each of the set-top processing units 108 or playback units 109 has a television 110 connected thereto for viewing of the video data received and decrypted by the set-top processing unit 108 or playback unit 109.

Further, other devices such as a residential gateway 114, may be connected with the network 105 and associated with user-subscribers. The residential gateways 114, in turn, may be connected to television(s) 110 or personal computer(s) 116, or both. The present video-on-demand system 100 utilizes unused storage on a hard-disk of the residential gateway 114 to store movie data similar to the set-top processing units. The residential gateway 114 is also configured to be turned “ON” most of the time and serves to present the personal computer 116 connected thereto with access to wider area networks, such as the Internet via the local network 105 and other data services provided thereon.

Throughout the remainder of this document, the set-top processing units 108, residential gateways 114, computers (e.g., personal computers) 116 or any other units that have the capability to store and stream video data onto the network line 107 will be referred to collectively as local processing units. Also, for instances where the local processing unit is described as being used in receiving and decrypting video data, the term “local processing unit” is also inclusive of playback units 109.

Further connected to the network 102 are a back-up media server 118 and a transaction processing server 120. The back-up media server 118 is used to store movie and video data, such as infrequently requested movies, for example. The transaction processing server 120 serves to conduct transaction processing with user-subscribers via their corresponding local processing units, such; as in pay-per-view arrangements or any other transactional type arrangement requiring transfer of credits or monies for access to movie data.

As discussed previously, the local processing units may be utilized for their unused memory, particularly unused hard-disk space, to distributively store a number of video or movie titles. Hence, the movie data resides primarily on devices in the local networks 105, which serve or stream movie data to one another over a local network line, such as network line 107, thereby reducing latency for delivery of movie data in a video-on-demand system and decreasing the amount of bandwidth necessary to provide a video-on-demand system.

Because the local processing units such as the set-top processing units 108 or residential gateways 114, will not necessarily know location of movie data when requests are made via these devices, the distributed database server 104 is provided for communicating locations of local processing that are storing the requested movie and also verifies that these devices are on-line. Thus, the database server 104 serves to direct and facilitate delivery of movie data from one or more of the local processing units to other local processing units located in the same local network 105 when the particular requested movie is stored within the local processing units.

The database server 104 also serves to receive requests from user-subscribers via local network line 107 and network 102 for particular movies or multimedia data. Moreover, the distributed database server 104 maintains a management database comprised of metadata and location data that tracks where particular movie data is stored on the array of local processing units within a local network 105. Finally, another function of the distributed database server 104 is to sequence communication with the management database to control the serving of a movie from one or more of the local processing units to a requesting local processing unit.

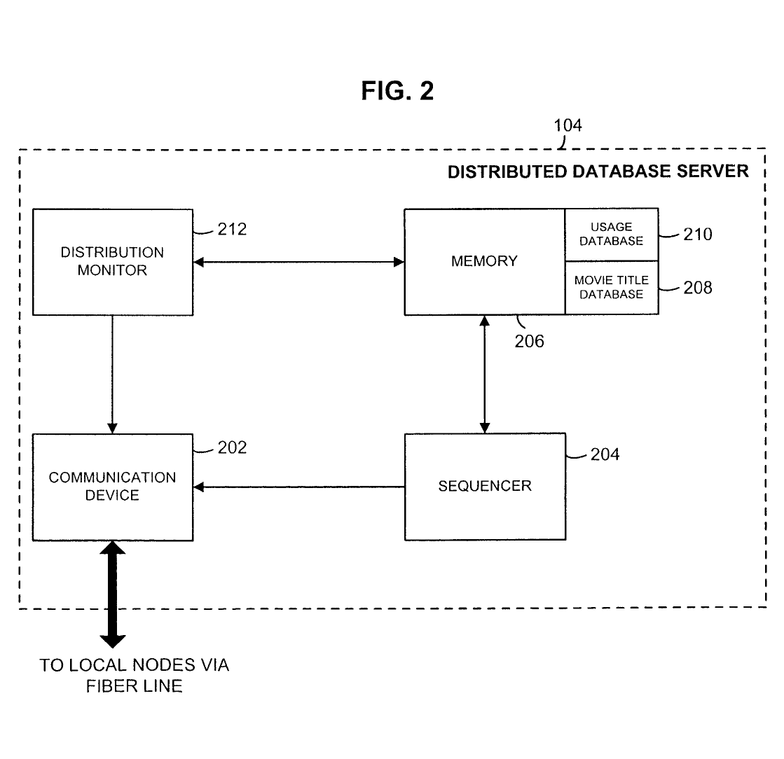

An example of a distributed database server 104 is illustrated in FIG. 2. As shown, the database server includes a: communication device 202 that is configured to receive requests from local processing units (e. g., set-top processors 108) via the network 102 and network 107. The communication device 202 is, in turn, in communication with a sequencer 204. The sequencer 204 is in further communication with a database memory 206 and serves to determine, through accessing information stored in the database memory 206, the sequence of local processing units serving data to requesting local processing units. Contained within the memory 206 may also be a movie title database 208 containing metadata concerning movie titles and other indices and a usage database 210, which is used to track usage information, which will be described later. Further included in the distributed database server 104 is a distribution monitor 212 that manages the storage of movie data to ensure that movie data is redundantly stored, for example, on a number of local processing units to ensure reliability of service. It is noted that the components of the distributed database server 104 illustrated in FIG. 2 may be implemented as hardware, software or firmware.

Referring again to FIG. 1, during transfer of a movie, a local processing unit may go off-line. To prevent disruption of movie playback, if this particular local processing unit is providing data for a movie, another local user-subscriber's local processing unit must be able to provide the movie data content. The distribution monitor 212 within the distributed database server 104 serves to monitor the availability of local processing units and arbitrates which unit will stream the movie data. An alternative operating mode of the monitor 212's function may include responding to quality-of-service notifications that are issued by the requester's local processing unit. To effect this mode, the local processing units include either software, firmware or hardware that monitors the quality-of-service and, in turn, issues the notifications concerning the service quality to the database server 104. In either case of functionality described above, monitoring and arbitration is carried out via the sequencer 204 and the communication device 202. The local processing units are selected by the sequencer 204 of server 104 based on their availability and bandwidth.

The distributed database server 104 may also be configured to further select particular local processing units over others in order prevent devices from overloading their upload bandwidth. In cases where a movie title requested by a user-subscriber is not stored locally on the array of local processing units, the back-up media server 118 is provided for the purpose of providing movie content that is unavailable locally. Reasons for unavailability may be due to a number of causes, such as due to a lack of interest, insufficient local storage redundancy or that local processing units containing the movie data are off-line. Hence, within the distributed database server 104 the sequencer 204 is also configured to interact with the distribution monitor 212 to determine when a movie is unavailable from the local units and direct the back-up media server 118 to stream data over the network 102 to the particular local network 105 in which the requesting user-subscriber is located.

A further function of the distributed database server 104 is to store or “push” (i.e., ensuring data is stored) movie data to the local processing units, direct transfer of movie data between local processing units and/or gateways, and also to determine if stored movie data within these devices is inadvertently overwritten by a user-subscriber or is in some way corrupted. This functionality is accomplished by the distribution monitor 212 within the distributed database server 104. Typically, the database server 104 will direct multimedia data or movies stored in the back-up media server 118 to push data to particular local processing units when one of these above-enumerated conditions is detected by the distribution monitor 212.

Another function of the distributed database server 104 is to monitor during transfers of movies between local processing units when one or more of these devices go off-line, as mentioned previously. The distributed database server 104 continually monitors the serving of movies from local processing units to other local processing units and arbitrates which of the local processing units (or also the back-up media server 118), based on their availability and present upload bandwidth capability, will stream the movie data. Hence, the distributed database server 104 serves to selectively choose which of the processing units within the local network 105 may stream movie data without overloading its present upload bandwidth capacity.

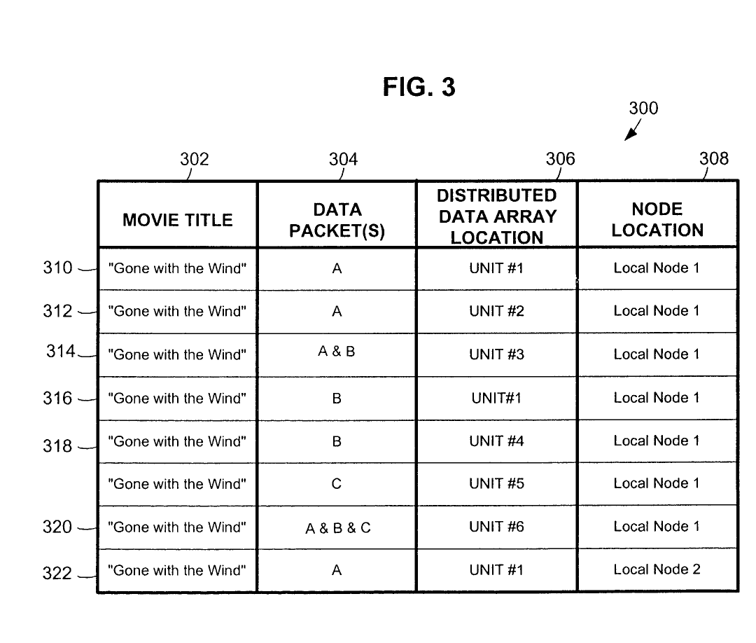

As mentioned previously, in order to manage streaming of movies from processing units to other processing units, the distributed database server 104 employs a memory 206 including a movie title database 208. As an example, FIG. 3 illustrates an example database table that may be employed within the movie title database 208 of the memory 206. As shown, the table 300 includes of a number of columns. A first column 302 stores a movie title or some other identifying indicia of a particular movie or multimedia data presentation. A next column 304 indicates a portion of the data for a particular movie title. A next column 306 stores data identifying a location within the distributed data array of one or more of the local processing units. Finally, a local node location column 308 is included to indicate which local network 105 the data resides within, particularly when the distributed database server 104 serves multiple local nodes 106 via network 102. As shown in a first row entry 310, a movie title (e. g., “Gone With The Wind”) has a first portion “A” of the movie data stored within a hard drive of a local processing unit No. 1 located in a local network served by local node No. 1. A second row entry 312 shows that the same data portion “A” of the same movie title is redundantly stored also in the hard-drive of a local processing unit No. 2 of the distributed data array within local node No. 1. As a variation, row entry 314 illustrates multiple data portions A and B stored within a local processing unit No. 3 connected to local node No. 1. Here, these data portions A and B may be stored as separate packets or, alternatively, may be interleaved such that a single packet may be streamed by unit No. 3 containing both data portions A and B. Hence, in the latter case when this interleaved packet arrives at a local processing unit performing decryption, a predetermined algorithm within the local processing unit will de-interleave the data and time-sequence the data such that it is displayed to the user-subscriber at the appropriate sequence time of the movie.

Row entry 316 illustrates that another data portion “B” of the same movie title may be also stored separately on unit No. 1 that is connected to local node No. 1. Row entry 318 illustrates storage of data portion B redundantly stored within a unit No. 4 also connected to local node No. 1.

A further row entry 320 illustrates data packets “A”, “B”, and “C” are stored within a local unit No. 6 connected to local node No. 1. Hence, the local unit No. 6 serves to redundantly store data packets that are also located in unit Nos. 1, 2, and 3 where packet “A” is also redundantly stored in unit Nos. 1, 2 and 3, packet “B” is redundantly stored in unit Nos. 1, 3 and 4 and packet “C” is redundantly stored in local unit 5.

A final example row entry 322 illustrates a data packet “A” of the same movie title stored on a local unit No. 1 within a local node No. 2. Also, although not shown, the data table 300 contains information concerning other movie titles, which may be also stored on some or all of the same local units that the first movie title (e. g., “Gone With The Wind”) is stored or stored on completely different local processing units.

As mentioned previously, the memory 206 also comprises a usage database 210 that accumulates usage statistics of the user-subscribers. Types of statistics accumulated may include the particular titles that are most frequently requested by system subscribers, the particular movie titles or presentations the system subscribers requested and/or viewed, and the genre of movie that is most frequently requested (i.e., Westerns, Dramas, Comedies, etc.) as well as frequency of viewing of particular movie titles. With these accumulated usage statistics, the distributed database server 104 selectively chooses which titles and types of movies and other multimedia data will be pushed or stored on the local units. For example, if subscribers served by a particular local network 105 statistically choose action/adventure movie titles more than other genres of movies, the distributed database movie server 104 will selectively push current action/adventure movies to the local processing units, whereas lesser viewed movie genres may remain stored on the back-up media server 118. This enables low latency for the user-subscribers for those types of movies which are most frequently requested by that particular group of user-subscribers. Moreover, the accumulated usage statistics may be extrapolated to “predict” which new movie titles will likely be selected by user-subscribers and the server 104 then programmed to ensure that these movies are pushed to the processing units and residential gateways in anticipation of requests by the user-subscribers.

For the purpose of performing transactional functions, such as in pay-per-view type video-on-demand systems, the transaction processing server 120 is provided. This transaction processing server 120 is configured to communicate with the distributed database server 104 either through the network 102 or, alternatively, via a dedicated connection (not shown). Further, the transaction processing server 120 is configured to communicate with each local data network 105 and the corresponding local processing units therein. Thus, when a user-subscriber requests a movie, the transaction processing server 120 may receive indication from the database server 104 to begin transaction processing or, alternatively, the server 120 may interact directly with the user-subscriber's local processing unit directly via the local network 105. Irrespective of how transaction processing is initiated within the server 120, the server 120 is configured to determine whether a user-subscriber is authorized to receive the movie streamed either from other local processing units or from the back-up media server 118. Moreover, the transaction server 120 may be configured to accept payment information from a requesting user-subscriber, such as through entry of credit card information, for example, or to determine if the requesting user-subscriber has sufficient credit in a credit database (not shown).

The transaction information occurring between the user-subscriber and the transaction processing server 120 may be effected via the user's local processing unit or via some other means, such as request over a telephone line, such as through an automated menu selection. When a user-subscriber has been determined as having authorization for viewing a requested movie as determined by the transaction processing server 120, the server 120, at the direction of the database server 104, may transmit a key code to the requesting user or, alternatively, may directly signal the distributed database server 104 to allow a local processing unit (or the backup server) to begin streaming the requested movie data. In the former case, the user receiving the key code would then manually or via an automatic process utilize the key code to signal local processing units that will stream the movie data or, alternatively, enable the requesting user's local processing unit to decrypt encrypted data streamed from the other local processing units. This latter technique affords streaming of only encrypted data on the local network 105, thereby preventing unauthorized users from readily viewing the movie data.

Referring again to FIG. 1, the local node 106 connected to the network 102 typically has a capacity of approximately 27 million bits per second (Mbps) for downstream transmission and 2 Mbps for upstream transmission, which is similar to existing local cable networks. Each node may then serve approximately 500 to 1000 homes via coaxial cable, as mentioned previously. In the presently disclosed system employing storage of movie data on local processing units, because all of these units may not be on-line all of the time, a minimum redundancy rate or ratio is required to achieve a desired reliability percentage. A number of local processing units or residential gateways storing redundant data to achieve a desired reliability percentage may be determined based on the following equation:

(1−d)ⁿ=(1−b) (1)

where d is a percentage of minimum processing units available, n is the processing unit redundancy and b is the desired reliability percentage. For example, it is assumed that 500 homes or processing units are connected to a local node 106 with a 10% processing unit availability during off-peak periods and that achievement of 99% reliability access to selected movies is desired. Also, this example takes into account that the total number of VHS quality (i.e., 1 Mbps data rate) movies that may be offered to all user-subscribers is approximately one two-hour movie for each excess of one gigabyte per hard-disk storage within the amalgamation of local processing units. Thus, given the assumed conditions and equation (1) above, 44 redundant local processing units, which each have enough excess storage space to store a movie title, would be required to guarantee 99% availability of a movie title.

In the following table, based on a 500-home local network, the available number of titles, assuming a 44-processing unit redundancy unit, that may be stored for different per unit excess disk capacity and encoding rates is illustrated.

Number of Titles on a 500 Home Local Network
(Assuming 99% reliability and 10% node availability)

| | |
|---|---|
| Hard-disk | Encoding Bit Rate (Mbps) |

| Capacity (GB) | 0.5 | 0.75 | 1 | 2 |
|---|---|---|---|---|
| 5 | 126 | 84 | 63 | 32 |
| 10 | 253 | 168 | 126 | 63 |
| 20 | 505 | 337 | 253 | 126 |
| 30 | 758 | 505 | 379 | 189 |
| 50 | 1263 | 842 | 631 | 316 |

As may be seen from the above table, if each of the user-subscribers have an excess hard-disk capacity of 5 gigabytes, for example, the number of VHS-quality titles (MPEG-2 @ 1 Mbps) that may be stored on a local network is approximately 63. As may further be seen, when the excess hard-disk capacity approaches 50 gigabytes, the number of VHS-quality titles stored locally is over 600. In the next generation of hard-disks having fixed memory spaces of approaching 500 gigabytes, for example, such excess capacities will not be uncommon. Moreover, even greater numbers of movie titles well into the thousands may be stored using advanced compression such as RealVideo, H.26L or Microsoft Windows Media®.

The movie data that is stored on the hard-disks of the local processing units may be encoded and encrypted in one of several forms. For compatibility with existing hardware decoders, MPEG-2 is preferable. MPEG-2, however, does not efficiently utilize hard-disk space and bandwidth as compared to next-generation video coding tools such as MPEG-4, RealNetworks, Microsoft Windows Media®, and H.26L. Using these enumerated next-generation encoding techniques, a user-subscriber would have the capability to even more efficiently decode the encoded video data. In these video coding tools, the encoded data is preferably packetized and served from the set-top processing units 108 or residential gateways 114 to other set-top processing units 108, gateways 114 or simply playback boxes 109 having only decoding capability. With these types of coding, the packetized data would then be accumulated by the, local processing units, buffered and composed into a playable stream in near real-time, provided sufficient bandwidth exists on the local network 105. Alternatively, the packetized data may be accumulated and the movie played off-line after all of the data has been accumulated.

The data streamed from the local processing units to other local processing units may be accomplished using time division multiplexing (TDM) or non-TDM. That is, in TDM the data packets may be sent sequentially using time division, such that a receiving local processing unit receives movie data in a sequential order as it will be ultimately played back. In non-TDM systems, further flexibility may be afforded by accommodating for variable packet delays on the local network 105. Thus, packets streamed to a playback user may be sent out of order with respect to their ultimate time playback sequence. Moreover, redundant data may further be sent to the playback user to compensate for any losses, delay, or loss of data in the network 105. Thus, each playback user would have included in their local processing unit a composition engine that would arbitrate between redundant data received and assemble data in the correct time sequence for playback. Additionally, data may be interleaved in a frame containing multiple packets to minimize line losses. Once received at the playback user, the interleaved data would then be de-interleaved and assembled in the proper order for playback.

In the illustrated system, a greater number of residential gateways 114 used as local processing units adds particular economy to the system. Residential gateways are typically turned “ON” most of the time, especially when called upon to provide services such as IP telephony. This high level of up-time substantially decreases the amount of storage redundancy needed since the percentage of minimum availability increases. Referring to the previously disclosed example utilizing a 99% target quality of service, the number of redundant storage locations, assuming the residential gateways are 50% reliable, would be 7 as determined by equation (1). This substantially reduces the number of local devices required for storage in order to provide a large movie title selection. Furthermore, the use of residential gateways also allows the service of the presently disclosed system to be economically feasible with fewer number of homes per local network.

As mentioned previously, providing redundancy into the present video-on-demand system to account for a low percent of off-line processing units or residential gateways affords a desired quality of service. Each of the local processing units or residential gateways, however, will have a finite up-load bandwidth, which is typically lower than the maximum down-load bandwidth. In existing cable networks, for example, this disparity will limit a local processing unit to serving approximately one movie title at a time, at most. Hence, for movie titles that are most frequently viewed, stored movie data is distributed over a large number of local processing units. When movie data requested is not available on one of the local processing units, the data may be served by the back-up media server 118 under the direction of the distributed database server 104. Moreover, when movie data is sent from the back-up server 118, the data may be cached on the hard-disks of the local processing units, provided enough storage capacity is available, so that this movie data is readily available on the local network, especially if the movie title is frequently viewed by the requesting user or others of the user-subscribers in the local network 105.

A further function of the distributed database server 104 is to refresh video data content stored on the local processing units. For example, when specific movie titles become less popular, the distributed database server 104 notes the reduced frequency of requests and replaces the movie title with newer or more frequently viewed video data. Preferably, the distributed database server 104 accomplishes this refreshing of movie data by directing the back-up media server 118 to stream or push movie data to either the processing units 108 or the residential gateways 114. Additionally, the distributed database server 104 is configured to conduct refreshment of video data at times when this process is most efficient, namely during off-peak hours when the bandwidth requirements of the user-subscribers is lower. Thus, the system may utilize bandwidth without increasing system costs by efficiently utilizing the extant bandwidth capacity of the local networks 105.

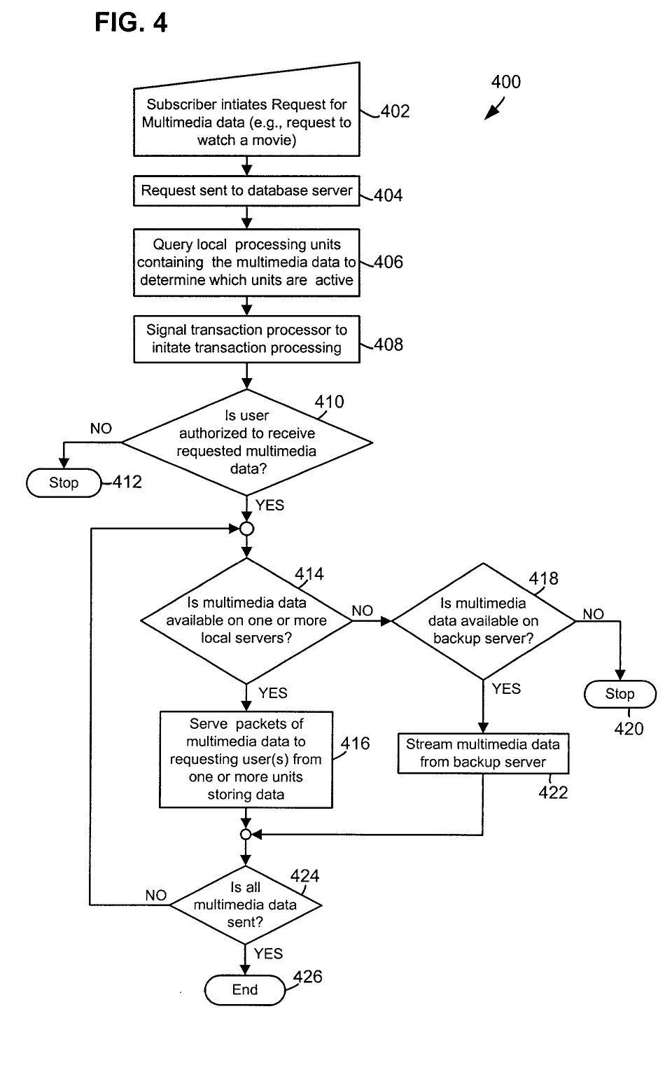

In operation, the disclosed video-on-demand system executes the 400 illustrated in FIG. 4. In this program, a subscriber first initiates a request for multimedia data, such as requesting a movie (block 402). The request is sent to the distributed database server 104 (block 404), via the user's local processing unit or playback box 109. The distribution monitor 212 of the distributed database server 104 then queries the local processing units that contain the requested multimedia data to determine which of the local processing units are active (block 406). Concurrently or immediately after the query (block 406), the transaction processing server 120 is signaled to initiate transaction processing (block 408). This transaction processing as previously described, may be initiated with a direct communication link between the requesting user-subscriber via their respective local processing unit or via an alternative communication connection with the distributed database server 104.

The transaction processing server 120 then determines if the requesting user-subscriber is authorized to receive the requested multimedia data (block 410). If the user is not authorized, the process stops (block 412) and a rejection message is sent to the requesting user. On the other hand, if the user is authorized to receive the requested video data, control proceeds to block 414 where the distribution user 9 and 212 of the distributed database server determines if the requested data is available on one or more of the local processing units. If the data is available on one or more of the local processing units, the local unit(s) are signaled by the sequencer 204 to serve packets of the multimedia data to the requesting user or users (block 416).

Alternatively, if at block 414, the database server 104 determines that the multimedia data is not available on one of the local processing units, the distribution monitor 212 of the database server 104 then determines whether the data is available on the back-up server 118 (block 418). If the data is not available on the back-up server 118, the process stops (block 420) and preferably some indication is given to the requesting user that the video data is unavailable. On the other hand, if the data is present on the back-up media server 118, the sequencer 204 directs the server 118 to stream the requested multimedia requested data to the requesting user or users (block 422).

Periodically during streaming of data from either the local servers or the back-up server, the distributed database server 104 queries to determine if all of the requested data has been sent (block 424). If all of the data has not been sent, control loops back to decision block 414 for a repetition of the above-described determinations and streaming of the requested data. When all of the data has been sent (block 424), the procedure ends, (block 426).

While looping through blocks 414-424, (block 414) it may be determined that a particular local processing unit 108 has become unavailable to stream the particular requested video data. For example, when a local processing unit streams a data stream 122 to another local processing unit becomes interrupted (as indicated by a cross-out “X” labeled with reference number 124 in FIG. 1), the distributed database server 104 detects the loss of this unit and the sequencer 204 of the server 104 directs another local processing unit to provide an alternate streaming of the data, such as is indicated by path 126 in FIG. 1. The distribution monitor 212 of the database server 104 continually monitors the availability of the local processing units as to their capability to stream the video data. Thus, additional local processing units that store requested data may be called upon to stream data whenever a unit currently streaming data becomes unavailable or has supplied its particular portion of the video data.

The distribution monitor 212 of the database server 104 also monitors whether a particular hard-drive of a local processing unit currently contains sufficient memory space to store data. Also, it checks whether each of the local processing units are properly functioning such that they are able to provide streaming of video data.

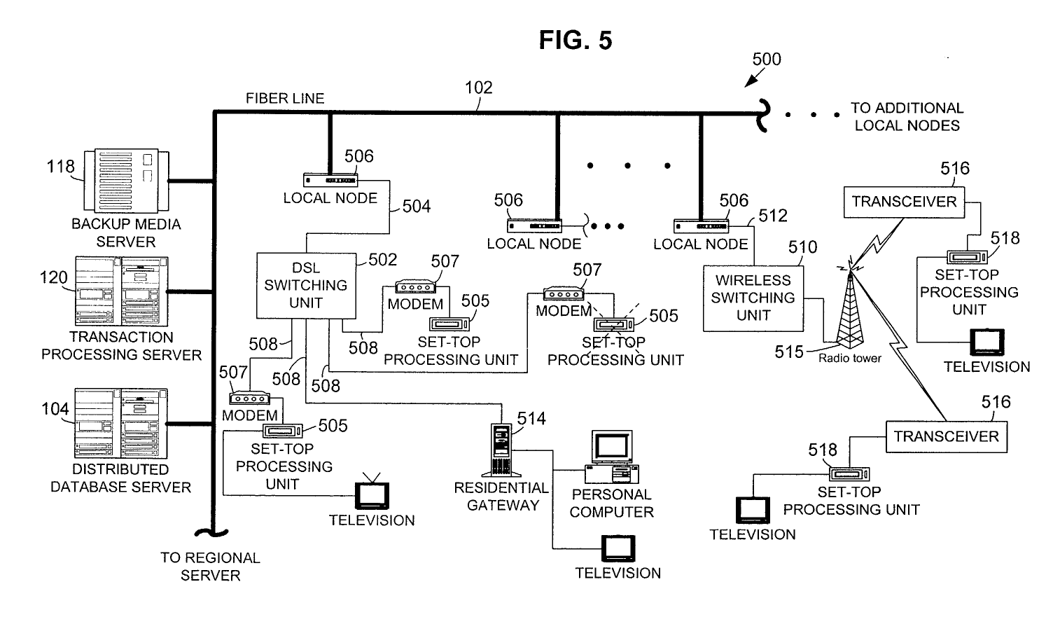

The illustrated video-on-demand system is alternatively applicable to other types of networks besides cable networks. As an example, FIG. 5 illustrates usage of the system with digital subscriber line (DSL) and wireless networks. With respect to application with a DSL network, an example application includes a DSL switching unit 502 that is connected to a local node 506 via a network connection 504. The DSL switching unit 502 works in conjunction with the DSL router (not shown) as a device go-between providing data access between user-subscribers set-top processing units 505 or gateways 514. A limitation of DSL networks, however, is a large asymmetry between the upload and download bandwidth capacities. That is, DSL systems typically provide a much larger download bandwidth than the upload bandwidth. Thus, when applying the presently disclosed video-on-demand system in a DSL network, the required redundancy is increased many fold. However, in typical DSL systems, a modem 507 that connects to the switching unit 502 (and ultimately the router), via a plain-old telephone service (POTS) twisted pair 508, is typically on most of the time. Additionally, residential gateways 514 similar to the residential gateways 114 used in the system of FIG. 1, having DSL communication capabilities may also be employed, and are also typically on most of the time. Thus, the increased required redundancy is offset by the much higher up-time of the DSL modems 507 and residential gateways 514 comprising the DSL network.

In another application, a wireless switching unit 510 may be connected to a local node 506 via a network connection 512. The wireless switching unit 510 is, in turn, connected to a radio frequency antenna 515 that transmits signals to and receives signals from transceivers 516. These transceivers 516 are configured to transmit and receive the packetized video data between set-top processing units 518 connected thereto or other types of local processing units (not shown). The application of the present video-on-demand system under the control of the distributed database server 104 would process requests for movies from local processing units, such as the set-top processing units 518 by the transceiver 516, antenna 515 and wireless switching unit 510 to initiate streaming of data between set-top processing units 518 via the switching unit 510. The wireless switching unit 510 also serves to effect communication between the database server 104 (as well as the back-up media server 118) and the local processing units as well as addressing and directing video data packets that are being streamed from one local processing unit to another requesting local processing unit viewing the video data.

Although certain apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. A video on demand system comprising:
a local data network;
a plurality of local processing units in the local network, the local processing units being associated with corresponding system subscribers and having a corresponding memory that is configured to store multimedia data; and
a database server configured to deliver multimedia data from a first one of the local processing units to a second one of the local processing units.

2. A system as defined in claim 1, wherein each of the local processing units comprises one of a set-top device, a residential media gateway and a personal computer.

3. A system as defined in claim 1, wherein the database server is configured to receive a request for a particular multimedia data set from the second local processing unit, to determine which of the local processing units store data in the particular multimedia data set, and to direct at least one of the determined local processing units to stream at least some of the data in the particular multimedia data set over the local data network to the second local processing unit.

4. A system as defined in claim 3, further comprising:
a backup server in communication with the local data network, the backup server being configured to stream multimedia data to the second local processing unit when at least some of the data in the particular multimedia data set is not stored in the memories of the local processing units.

5. A system as defined in claim 3, further comprising:
a backup server in communication with the local data network, the backup server being configured to stream multimedia data to the second local processing unit when at least one of the determined local processing units is unable to stream data to the second local processing unit.

6. A system as defined in claim 1, further comprising:
a transaction server in communication with the local data network, the transaction server configured to determine whether a requesting system subscriber is authorized to receive a requested multimedia data set.

7. A system as defined in claim 6, wherein the transaction server is further configured to accept payment information from the requesting system subscribers and to selectively authorize delivery of the requested multimedia set to the requesting system subscriber based on the payment information.

8. A system as defined in claim 7, wherein the payment information is transmitted to the transaction server from the requesting system subscribers via local processing units and the local data network.

9. A system as defined in claim 1, wherein the local data network comprises at least one of fiber line, coaxial cable line and wireless transmission.

10. A system as defined in claim 1, wherein redundant multimedia data is stored within at least two or more of the local processing units.

11. A system as defined in claim 1, wherein the database server is further configured to develop usage information concerning types of multimedia data requested by the system subscribers and to select types of multimedia data to be stored on the local processing units based on the usage information.

12. A system as defined in claim 1 wherein the multimedia data comprises a video.

13. A method for providing video on demand service comprising:
storing video data within a plurality of local processing units in a local network, the local processing units being associated with corresponding subscribers of the video on demand service;
receiving at a first computer a request for particular video data from a first one of the local processing units; and
streaming the particular video data to the first one of the local processing units from at least a second one of the plurality of local processing units via the local network.

14. A method as defined in claim 13 wherein streaming the particular video data further comprises:
the first computer instructing the at least a second one of the local processing units to provide the particular video data.

15. A method as defined in claim 13, further comprising:
determining whether the second one of the local processing units is available to stream the particular video data; and
if the second local processing unit is unavailable, providing the particular video data from one of a third local processing unit and a backup server connected to the network.

16. A method as defined in claim 15, further comprising:
determining that the third processing unit is unavailable to stream the particular video data; and
if the third processing unit is unavailable, providing the particular video data from a fourth processing unit.

17. A method as defined in claim 13, further comprising:
storing at least a portion of the particular video data in the first local processing unit;
serving a first portion of the particular video data to the first local processing unit from the first local processing unit; and
serving a second portion of the particular video data to the first local processing unit from the second local processing unit at the direction of the first computer.

18. A method as defined in claim 13, further comprising:
developing usage information concerning types of data requested by the subscribers; and
selectively storing data in the local processing units based on the developed usage information.

19. For use in a video on demand system, a database server comprising:
a distribution monitor for managing storage of multimedia data in a plurality of local processors associated with subscribers;
a communication device to receive a request from a first one of the local processors to access a program in the multimedia data;
a management database that maps the storage locations of the multimedia data; and
a sequencer in communication with the management database to control serving of the program from at least a second one of the local processors to the first local processor.

20. A database server as defined in claim 19 wherein the sequencer is configured to determine when data related to the program is unavailable from the second local processor storing the data and to direct a backup server to stream the data to the first local processing unit when the unavailability determination is made.

21. A database server as defined in claim 19, wherein the distribution monitor is configured to manage storage of the multimedia data by writing data to one or more of the local processors; transferring data between the local processors; and monitoring the local processors to determine if data is overwritten.

22. A database server as defined in claim 19, wherein the sequencer is further configured to direct a backup server to deliver program data to the first local processor when the program data cannot be delivered by any of the local processors.

23. A database server as defined in claim 19, wherein the sequencer is configured to communicate with a transaction server, wherein the transaction server is configured to determine whether a requesting subscriber user associated with the first local processor is authorized to access the program and wherein the transaction server communicates authorized information to the database server.

24. A database server as defined in claim 19, wherein the sequencer is further configured to develop usage information concerning types of data requested by the subscribers; and the distribution monitor is configured to selectively store data in the local processor based on the usage information.

25. A method of monitoring a distributed video on demand system comprising:
identifying an inability of a first local unit to deliver a first portion of a movie stored within the first local unit to a second local unit;
determining whether a third local unit has the ability to deliver the first portion of the movie;
storing the first portion of the movie in the third local unit if the third local unit is determined to have the ability to deliver the first portion of the movie; and
logging the location of the first portion of the movie in a table.

26. A method as defined in claim 25, wherein identifying an ability of a first local unit comprises at least one of: checking whether the first local unit is currently powered up, checking whether a hard drive within the first local unit has sufficient memory space to store the first data set, and checking whether the local unit is properly functioning.

27. A method as defined in claim 25, wherein determining whether a third local unit has the ability to deliver the first portion of the movie comprises at least one of: checking whether the third local unit is currently powered up, checking whether a hard drive within the third local unit has sufficient memory space to store the first data set, and checking whether the third local unit is properly functioning.

28. A method as defined in claim 25, wherein the table correlates: (a) the locations of the local units storing data, (b) identities of the stored data.

29. A method as defined in claim 28, wherein the identities of the stored data include movie titles and particular segments of the stored data.

30. A method of monitoring a distributed video on demand system comprising:
checking to see if a predetermined redundancy ratio is maintained for a first data set to be stored in local processors in the system;
if the predetermined redundancy ratio is not met, determining a number of additional local processors to store the first data set to meet the predetermined redundancy ratio; and
storing the first data set in the additional number of local processors to meet the predetermined redundancy ratio.

31. A method as defined in claim 30, wherein the predetermined redundancy ratio is determined based on a desired reliability and a minimum availability percentage of local processors.

32. A method for supplying data in a distributed video on demand network comprising:
at a first time, supplying a first set of data associated with a requested video from a first local device associated oath a first subscriber to a second local device associated with a second subscriber; and
at a second time, supplying a second set of data associated with the requested video from a third local device associated with a third subscriber to the second local device.

33. A method as defined in claim 32 wherein the first and third local devices are directed by a distributed database server.

34. A method as defined in claim 32, further comprising:
at a third time, storing a third set of data from a backup server to the second local device.

35. A method for supplying data in a distributed video on demand network comprising:
at a first time, supplying a first set of data associated with a requested video from a first local device associated with a first subscriber to a second local device associated with a second subscriber; and
at a second time, supplying a second set of data associated with the requested video from a backup server.

36. A method as defined in claim 35, further comprising:
prior to the first time, performing an access transaction between the second local device and a transaction server.

37. A method as defined in claim 35, further comprising:
prior to the first time, performing an access transaction between the second subscriber and a transaction server.

38. A method for providing multimedia data in a distributed video on demand network comprising:
storing multimedia data in a first local device associated with a first network subscriber; and
serving the multimedia data from the first local device to a second local device associated with a second network subscriber in response to a request to a database server for the multimedia data from the second network subscriber via the second local device to the database server.

39. A method as defined in claim 38, further comprising:
storing the multimedia data in a third local device associated with a third network subscriber; and
serving the multimedia data from the third local device to the second local device at the direction of the database server when the database server determines that the first local device is unable to serve the multimedia data.

40. A method as defined in claim 39, the method further comprising:
serving the multimedia data from a backup server at the direction of the database server when the database server determines that the first and third local devices are unable to serve the multimedia data.

41. A method as defined in claim 40, further comprising:
initiating a transaction between the database server and the second network subscriber in response to the request to the database server for the multimedia data by prompting the second network subscriber to provide authorization information to a transaction server via the second local device; and
signaling the database server from the transaction server to allow the multimedia data to be served to the second local device after the transaction process is completed.

42. A method as defined in claim 41, wherein the authorization information includes at least one of payment information and a user access code.

43. A method as defined in claim 38, wherein the multimedia data is selectively stored in the first and third local devices based on accumulated usage information concerning types of multimedia data requested by the first, second and third subscribers.

44. For use in a distributed video on demand network, an apparatus comprising:
a database server configured to manage distributed storage of multimedia data across the network on a plurality of local units associated with system subscribers;
a first local unit in the plurality of local units configured to request and receive portions of the multimedia data; and
a second local unit in the plurality of local units configured to stream a first portion of the multimedia data to the second local unit in response to a command from the database server, the database server generating the command in response to a request for the multimedia data from the second local device.

45. An apparatus as defined in claim 44, further comprising:
a third local unit in the plurality responsive to a second command from the database server to stream a second portion of the multimedia data to the first local unit after the second local unit has delivered the first portion of the multimedia data.

46. An apparatus as defined in claim 44, wherein the database server is configured to direct a third local unit to stream the first portion of the multimedia data to the second local unit when the database server determines that the second local unit is unable to serve the multimedia data.

47. An apparatus as defined in claim 44, further comprising:
a backup server configured to serve the first portion of the multimedia data to the first local unit when at least one of the second local unit and a third local unit is unable to serve the first portion of multimedia data.

48. An apparatus as defined in claim 44, further comprising:
a backup server configured to serve the first portion of the multimedia data to the first local unit when none of the local units in the plurality store the first portion of the first portion of the multimedia data.

49. An apparatus as defined in claim 44, further comprising:
a transaction server responsive to a request for the first portion of the multimedia data from the first local unit to determine whether to allow the database server to serve the first portion of the multimedia data to the first local device.

50. An apparatus as defined in claim 49, wherein the transaction server determines whether to serve based on one or more of payment information and a user access code associated with the first local unit.

51. A software program stored on a medium for providing video on demand service comprising:
a first software storing video data within a plurality of local processing units in a local network, the local processing units being associated with corresponding subscribers of the video on demand service;
a second software receiving a request at a server for particular video data from a first one of the local processing units; and
a third software streaming the particular video data to the first one of the local processing units from at least a second one of the plurality of local processing units via the local network.

52. A software program as defined in claim 51 wherein the third software streaming the particular video data further comprises instructing the at least a second one of the local processing units to provide the particular video data.

53. A software program as defined in claim 51, further comprising:
a fourth software determining whether the second one of the local processing units is available to stream the particular video data; and causing the particular video data to be delivered from one of a third local processing unit and a backup server connected to the network when the second local processing unit is unavailable.

54. A software program as defined in claim 53, the fourth software further determining that the third processing unit is unavailable to stream the particular video data and causing the particular video data to be delivered from a fourth processing unit when the third processing unit is unavailable.

55. For use in a video on demand system having a database server configured to control delivery of video data between local processing units connected within a local network, an apparatus comprising:
a local processing unit connectable to the local network, the unit having a storage device configured to store video data and wherein the local processing unit is configured to transmit stored video data to other local processing units connected within the local network at the direction of the database server.

56. An apparatus as defined in claim 55, wherein the local processing unit comprises one of a set-top device, a residential media gateway and a personal computer.

57. An apparatus as defined in claim 55, wherein the local processing unit is further configured to transmit encrypted video data over the local network to the other local processing units.

58. An apparatus as defined in claim 55, wherein the local processing unit is further configured to receive video data from at least one other local processing unit connected to the local processing unit, to determine a quality of service of the received video data and transmit a notification of the determined quality of service to the database server.

59. An apparatus as defined in claim 55, wherein the local processing unit is further configured to receive encrypted video data over the local network from the other local processing units and decrypt the encrypted video data for playback by the local processing unit using a key code received at the direction of the database serve.

60. An apparatus as defined in claim 59, wherein the local processing unit is further configured to decrypt the encrypted video data using a key code received at the direction of the database serve.
